(19) United States
(12) Patent Application Publication
(10) Pub. No.: US 2006/0145249 A1
(43) Pub. Date: Jul. 6, 2006

(54) LDMOS transistor

(75) Inventor: Suk Kyun Lee, Bucheon-city (KR)

Correspondence Address: MCKENNA LONG & ALDRIDGE LLP, 1900 K STREET, NW, WASHINGTON, DC, 20006, US

(73) Assignee: DongbuAnam Semiconductor Inc., Seoul (KR)

(21) Appl. No.: 11/319,486

(22) Filed: Dec. 29, 2005

(30) Foreign Application Priority Data
Dec. 30, 2004 (KR) 10-2004-0117437

(51) Int. Cl. H01L 29/76

(52) U.S. Cl. 257/335

(57) ABSTRACT

A lateral double-diffused metal oxide semiconductor transistor (LDMOS) transistor includes a semiconductor substrate of a first conductivity; an extended drain region of the first conductivity formed in a surface region of the semiconductor substrate; and a depletion region, formed in the extended drain region, including first and second impurity regions sequentially embedded below a surface of the extended drain region, the first embedded impurity region being of a second conductivity and the second embedded impurity region being of the first conductivity.

### CROSS-REFERENCE TO RELATED APPLICATION

This application claims the benefit of Korean Patent Application No. 10-2004-0117437, filed on Dec. 30, 2004, which is hereby incorporated by reference as if fully set forth herein.

### BACKGROUND OF THE INVENTION

1. Field of the Invention

The present invention relates to a semiconductor device, and more particularly, to a lateral double-diffused metal oxide semiconductor (LDMOS) transistor. Although the present invention is suitable for a wide scope of applications, it is particularly suitable for high breakdown voltage and enhanced on-resistance characteristics.

2. Discussion of the Related Art

Referring to FIG. 1, illustrating an LDMOS transistor according to the related art, a p-type body 120 and an n⁻ extended drain region 130 are spaced apart from one another on an n⁻ semiconductor substrate 100 having an active area defined by a device isolation layer 110. An n+ source region 140 is provided on the p-type body 120. An upper part of the p-type body 120, which is overlapped by a gate insulating layer 160 and a gate conductive layer 170 near the n⁺ source region 140, is a channel 121. An n⁺ drain region 150 is provided on the n⁻ extended drain region 130.

The gate insulating layer 160 and the gate conductive layer 170 are sequentially stacked on the channel 121. A gate spacer layer 180 is formed on a sidewall of the gate conductive layer 170. Before the gate spacer layer 180 is formed, primary ion implantation is carried out. After the gate spacer layer 180 has been formed, secondary ion implantation is carried out for double diffusion. Hence, a double-diffused MOS transistor structure is completed. The n⁺ source and drain regions 140 and 150 are electrically connected to source (S) and drain (D) electrodes, respectively.

In the conventional LDMOS transistor, impurity density of the n⁻ extended drain region 130 used as a drift region needs to be raised to enhance on-resistance characteristics of a device. There is, however, a trade-off between the on-resistance characteristics of the device and its breakdown voltage characteristics. In other words, if the impurity density of the n⁻ extended drain region 130 is increased, a lower breakdown voltage results.

### SUMMARY OF THE INVENTION

Accordingly, the present invention is directed to an LDMOS transistor that substantially obviates one or more problems due to limitations and disadvantages of the related art.

The present invention provides a lateral double-diffused metal oxide semiconductor (LDMOS) transistor, which increases the impurity density of a drift region without lowering a breakdown voltage and by which on-resistance characteristics can be enhanced.

Additional advantages, objects, and features of the invention will be set forth in the description which follows and will become apparent to those having ordinary skill in the art upon examination of the following. The objectives and other advantages of the invention may be realized and attained by the structure particularly pointed out in the written description and claims hereof as well as the appended drawings.

To achieve these objects and other advantages in accordance with the invention, as embodied and broadly described herein, there is provided an LDMOS transistor comprising a semiconductor substrate with a first conductivity; an extended drain region with the first conductivity formed in a surface region of the semiconductor substrate; and a depletion region, formed in the extended drain region, including first and second impurity regions sequentially embedded below a surface of the extended drain region, the first embedded impurity region having a second conductivity and the second embedded impurity region having the first conductivity.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention, illustrate exemplary embodiments of the invention and together with the description serve to explain the principle of the invention. In the drawings:

FIG. 1 is a cross-sectional diagram of an LDMOS transistor according to the related art; and

FIG. 2 is a cross-sectional diagram of an exemplary LDMOS transistor according to the present invention.

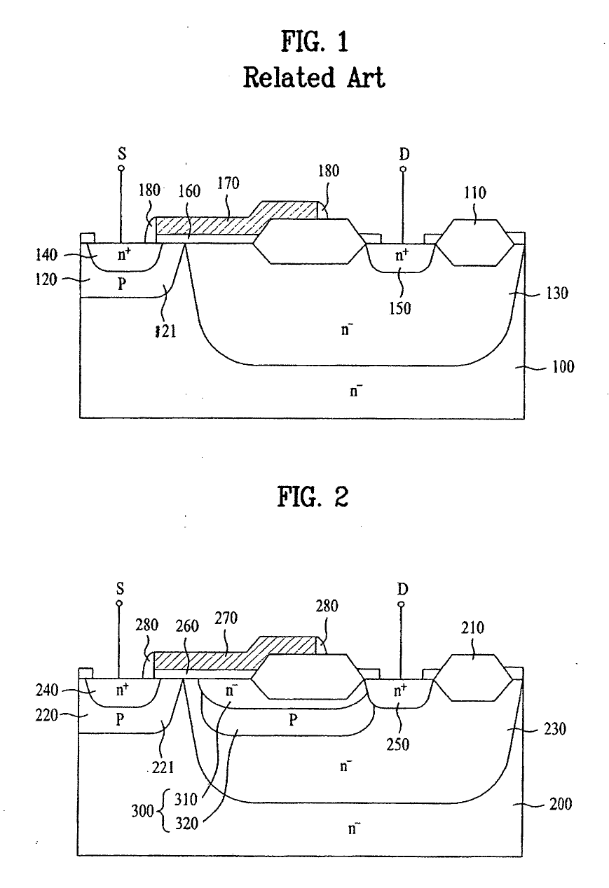

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

Referring to FIG. 2, illustrating an exemplary LDMOS transistor according to the present invention, a p-type body 220 and an n⁻ extended drain region 230 spaced apart from one another on an n⁻ semiconductor substrate 200 having an active area defined by a device isolation layer 210. An n+ source region 240 is provided on the p-type body 220. An upper part of the p-type body region 220, which is overlapped by a gate insulating layer 260 and a gate conductive layer 270 near the n⁺ source region 240, is a channel 221. An n⁺ drain region 250 is provided on the n⁻ extended drain region 230.

A depletion region 300 is provided on the n⁻ extended drain region 230 between the p-type body 220 and the n⁺ drain region 250. The depletion region 300 includes a p-type impurity region 320 and an n⁻ impurity region 310, which are sequentially embedded below a surface of the n⁻ extended drain region 230. The n⁻ impurity region 310 and the p-type impurity region 320 of the depletion region 300 are fully depleted such that a specific breakdown voltage can be obtained. Simultaneously, by increasing the impurity density of the n⁻ extended drain region 230 and by reducing the length of a drift region of the n⁻ extended drain region, enhanced on-resistance characteristics can be obtained while maintaining the same breakdown voltage.

A gate stack including the sequentially stacked gate insulating and conductive layers 260 and 270 is provided on the channel 221. A gate spacer layer 280 is formed on a sidewall of the gate conductive layer 270. Before the gate spacer layer 280 is formed, primary ion implantation is carried out. After the gate spacer layer 280 has been formed, secondary ion implantation is carried out for double diffusion. Hence, a double-diffused MOS transistor structure is completed. The n⁺ source and drain regions 240 and 250 are electrically connected to source (S) and drain (D) electrodes, respectively.

According to the present invention, by providing the fully depleted depletion region on the extended drain region, a desired breakdown voltage can be obtained. In addition, by increasing the impurity density of the n⁻ extended drain region and by reducing the length of the drift region of the n⁻ extended drain region, the present invention can obtain enhanced on-resistance characteristics with the desired breakdown voltage.

It will be apparent to those skilled in the art that various modifications can be made in the present invention without departing from the spirit or scope of the invention. Thus, it is intended that the present invention covers such modifications provided they come within the scope of the appended claims and their equivalents.

What is claimed is:

1. A lateral double-diffused metal oxide semiconductor (LDMOS) transistor, comprising:
a semiconductor substrate with a first conductivity;
an extended drain region with the first conductivity formed in a surface region of said semiconductor substrate; and
a depletion region, formed in said extended drain region, including first and second impurity regions sequentially embedded below a surface of said extended drain region, the first embedded impurity region having a second conductivity and the second embedded impurity region having the first conductivity.

2. The LDMOS transistor of claim 1, wherein the second embedded impurity region is embedded deeper than the first embedded impurity region.

3. The LDMOS transistor of claim 1, wherein the first embedded impurity region is nearer the surface of said extended drain region than the second embedded impurity region.

4. The LDMOS transistor of claim 1, wherein said semiconductor substrate has a predetermined upper region provided with a body of the second conductivity.

5. The LDMOS transistor of claim 4, further comprising:
a source region with the first conductivity provided on the body.

6. The LDMOS transistor of claim 4, wherein said extended drain region is spaced apart from the body.

7. The LDMOS transistor of claim 1, further comprising:
a gate stack provided on a channel within the body.

8. The LDMOS transistor of claim 1, further comprising:
a drain region with the first conductivity provided on said extended drain region.

9. The LDMOS transistor of claim 1, wherein the first conductivity is n-type and wherein the second conductivity is p-type.

10. A lateral double-diffused metal oxide semiconductor transistor, comprising:
a first conductive type semiconductor substrate;
a second conductive type body provided to a predetermined upper area of the semiconductor substrate;
a first conductive type source region provided on the body;
a first conductive type extended drain region spaced apart from the body on to the predetermined upper area of the semiconductor substrate;
a first conductive type drain region provided on the extended drain region;
a gate stack provided on a channel within the body; and
a depletion region provided on the extended drain region between the body and the drain region, the depletion region comprising first and conductive type impurity regions sequentially embedded from a surface of the extended drain region.
